(19) United States
(12) Patent Application Publication
(10) Pub. No.: US 2024/0312925 A1
(43) Pub. Date: Sep. 19, 2024

(54) SEMICONDUCTOR DEVICE, FABRICATING METHOD, MEMORY DEVICE AND DEVICE SYSTEM

(71) Applicant: YANGTZE MEMORY TECHNOLOGIES CO., LTD., Wuhan (CN)

(72) Inventors: Ping Mo, Wuhan (CN); Xinru Zeng, Wuhan (CN); Peng Chen, Wuhan (CN); Xin Feng, Wuhan (CN)

(21) Appl. No.: 18/204,039

(22) Filed: May 31, 2023

(30) Foreign Application Priority Data
Mar. 15, 2023 (CN) 202310251650.2

(51) Int. Cl. H01L 23/544; H01L 21/268; H01L 21/683; H01L 21/78; H01L 23/00; H01L 23/58

(52) U.S. Cl. CPC H01L 23/544; H01L 21/268; H01L 21/6836; H01L 21/78; H01L 23/562; H01L 23/564; H01L 23/585; H01L 2221/68327; H01L 2223/5446

(57) ABSTRACT

The present disclosure provides a semiconductor device, a fabricating method thereof, a memory device and a memory system. The disclosed semiconductor device comprises a first device, a dicing street adjoining the first device laterally, a metal structure located in the dicing street, and a stealth cleavage lane extending in the dicing street. A first orthogonal projection of the stealth cleavage lane on a lateral cross-section of the dicing street is distant from a second orthogonal projection of the metal structure on the lateral cross-section of the dici

### CROSS-REFERENCE TO RELATED APPLICATIONS

This application claims the benefit of priority to China Patent Application No. CN 2023102516502, filed on Mar. 16, 2023, the content of which is incorporated herein by reference in its entirety.

### TECHNICAL FIELD

Implementations of the present disclosure relate to the field of semiconductor technologies, and in particular to a semiconductor device, a fabricating method, a memory device and a memory system.

### BACKGROUND

During packaging processes for ultra-thin 3D NAND chips, in order to minimize the influence on the strength of the chips by the grinding and dicing process in packaging, a stealth dicing before grinding (SDBG) process is usually used to split a wafer into dies by cleavage in specified directions through stealth dicing and grind them on the backside to remove pure silicon therefrom, making the dies have a specified thickness. This process can be used to avoid mechanical damages to the strength of the dies caused by blade dicing. However, with multiplication of the number of layers in the memory array of a 3D NAND chip, the metal layer with an increased thickness causes that the dies cannot be cleaved in the specified direction in stealth dicing and in turn causes undesirable cracks in the dies, leading to a loss. Therefore, the power intensity and the number of dicing operations are increased in the stealth dicing by workers to separate dies with an increased thickness, which, however, increases the risk of laser scattering and lowers the yield. If a laser grooving process is introduced before the SDBG process, laser grooving needs to be performed on multiple positions of the whole wafer at the same time due to the disperse distribution of the metal layers in the wafer. This solution solves the problem of the SDBG process about the position of cleavage, however the strength of the dies is also reduced and meanwhile more scraps may be produced under laser irradiation.

### SUMMARY

Implementations of the present disclosure provide a fabricating method of a semiconductor device, a semiconductor device, a memory and a system to solve the technical problem in the prior art that the metal structures in the wafer will affect the directions of cracks generated in stealth dicing, thereby reducing the strength of chips.

In order to solve the above-mentioned technical problem, the present disclosure discloses the following technical solutions.

In the first aspect, a semiconductor device is provided, the semiconductor device including: a first device; a dicing street adjoining the first device laterally; and a stealth cleavage lane located in the dicing street; wherein the dicing street includes a metal structure, the stealth cleavage lane has a first orthogonal projection on the cross-section of the dicing street, the metal structure has a second orthogonal projection on the cross-section of the dicing street, and the first and second orthogonal projections have a space therebetween.

In connection with the first aspect, a second device is further included. The first device includes a first sealing ring and the second device includes a second sealing ring, and the dicing street is located between the first sealing ring and the second sealing ring.

In connection with the first aspect, the metal structure includes a first side edge and a second side edge disposed opposite to each other, the first side edge is closer to the first sealing ring than the second side edge is, the second side edge is closer to the second sealing ring than the first side edge is, and the stealth cleavage lane is preset between the first side edge and the first sealing ring.

In connection with the first aspect, the first device includes pads disposed on a side of the first sealing ring away from the dicing street.

In connection with the first aspect, the second side edge and the second sealing ring are spaced apart by at least one unit-length of distance, the stealth cleavage lane and the first sealing ring are spaced apart by at least two unit-lengths of distance, and the first side edge and the first sealing ring are spaced apart by at least three unit-lengths of distance.

In connection with the first aspect, one unit-length is 5 μm.

In connection with the first aspect, the first side edge and the first sealing ring are spaced apart by a first distance B and the second side edge and the second sealing ring are spaced apart by a second distance C with the first distance B larger than the second distance C.

In connection with the first aspect, the first distance B and the second distance C satisfy: 1<B/C≤4.

In connection with the first aspect, the stealth cleavage lane and the first sealing ring are spaced apart by a third distance A, wherein the first distance B and the third distance A satisfy: 1≤B/A≤3.

In connection with the first aspect, the stealth cleavage lane and the first sealing ring are spaced apart by the third distance A that has a value in the range of 5≤A≤10 μm.

In connection with the first aspect, the first distance B has a value in the range of 15≤B≤30 μm.

In connection with the first aspect, the second distance C has a value in the range of 5≤B≤15 μm.

In connection with the first aspect, the semiconductor device includes one or more of a memory array and a peripheral circuit.

In the second aspect, a fabricating method for a semiconductor device is provided, the method including: providing a first device and a dicing street adjoining the first device laterally on the front surface of a substrate; forming a metal structure and a stealth cleavage lane in the dicing street, the dicing street having a first orthogonal projection on the substrate, the metal structure having a second orthogonal projection on the substrate, and the first and second orthogonal projections having a space therebetween.

In connection with the second aspect, the method further includes: forming a second device on the substrate; and forming a first sealing ring in the first device and a second sealing ring in the second device with the dicing street formed between the first sealing ring and the second sealing ring.

In connection with the second aspect, the metal structure includes a first side edge and a second side edge, the first side edge is closer to the first sealing ring than the second side edge is, the second side edge is closer to the second sealing ring than the first side edge is, and when forming a metal structure, the first distance B between the first side edge and the first sealing ring is controlled to be larger than the second distance C between the second side edge and the second sealing ring.

In connection with the second aspect, the step of forming a metal structure and a stealth cleavage lane in the dicing street includes forming the stealth cleavage lane between the first side edge and the first sealing ring by stealth laser dicing; and the fabricating method further includes thinning the substrate from backside to form a thinned surface.

In connection with the second aspect, the fabricating method further includes: forming a protective layer at least on the dicing street before formation of the stealth cleavage lane, wherein the protective layer has marks disposed thereon to indicate the extending direction of the stealth cleavage lane.

In connection with the second aspect, the method further includes: covering the thinned surface of the substrate with a dicing tape; removing the protective layer; and performing die separation through expansion on the first device and the second device using the dicing tape to obtain singularized first device and second device.

In the third aspect, a memory including a memory array and a peripheral circuit is provided. The memory array or the peripheral circuit includes: a first device; a dicing street adjoining the first device laterally; and a stealth cleavage lane located in the dicing street; wherein the dicing street includes a metal structure, the stealth cleavage lane has a first orthogonal projection on the cross-section of the dicing street, the metal structure has a second orthogonal projection on the cross-section of the dicing street, and the first and second orthogonal projections have a space therebetween.

In the fourth aspect, a memory system is provided, the system including: a memory including a memory array and a peripheral circuit, wherein the memory array or the peripheral circuit includes: a first device; a dicing street adjoining the first device laterally; and a stealth cleavage lane located in the dicing street; wherein the dicing street comprises a metal structure, the stealth cleavage lane has a first orthogonal projection on the cross-section of the dicing street, the metal structure has a second orthogonal projection on the cross-section of the dicing street, and the first and second orthogonal projections have a space therebetween; and a controller electrically connected with the memory to control the memory to store data.

One of the technical solutions above has the following advantages or beneficial effects.

Compared with those in the prior art, a semiconductor device in the present disclosure includes: a first device; a dicing street adjoining the first device laterally; and a stealth cleavage lane located in the dicing street, wherein the dicing street includes a metal structure and a stealth cleavage lane, the stealth cleavage lane has a first orthogonal projection on the cross-section of the dicing street, the metal structure has a second orthogonal projection on the cross-section of the dicing street, and the first and second orthogonal projections have a space therebetween. In the present disclosure, the metal structure is offset in position from the stealth cleavage lane in the dicing street to avoid influence on formation of the modified layer by the metal structure and generation of transverse cracks in stealth dicing. Additionally, it is ensured that the stealth dicing will not affect the strength of chips and meanwhile the number of stealth dicing operations can be reduced, so that production costs of chips can be lowered, and yield of chips can be increased.

### BRIEF DESCRIPTION OF ACCOMPANYING DRAWINGS

In combination with the accompanying drawings, the technical solution and other beneficial effects of the application will become apparent through detailed description of specific implementations of the present disclosure.

FIG. 1 is a partially enlarged diagram of a wafer provided in accordance with an implementation of the present disclosure;

FIG. 2 is a partial top view diagram in an XY plane of a semiconductor device provided in accordance with an implementation of the present disclosure;

FIG. 3 is a structural cross-section diagram taken along A-A in FIG. 2 provided in accordance with an implementation of the present disclosure;

FIG. 4 is partial top view diagram in an XY plane of a semiconductor device in the prior art provided in accordance with an implementation of the present disclosure;

FIG. 5 is a structural cross-section diagram taken along B-B in FIG. 4 in the prior art provided in accordance with an implementation of the present disclosure;

FIG. 6 is a structural cross-section diagram of a wafer with a fracture in the prior art provided in accordance with an implementation of the present disclosure;

FIG. 7 is a flow diagram of a fabricating method for a wafer provided in accordance with an implementation of the present disclosure;

FIG. 8 is a structural top view diagram of a memory provided in accordance with an implementation of the present disclosure;

FIG. 9 is a main view structural diagram of a memory provided in accordance with an implementation of the present disclosure; and

FIG. 10 is a block diagram of a memory system provided in accordance with an implementation of the present disclosure.

Notes of Reference Numerals are as follows: 100—substrate; 110—stealth cleavage lane; 120—dicing street; 130—first sealing ring; 131—second sealing ring; 140—fracture; 200—metal structure; 210—second side edge; 220—first side edge; 300—pad; 400—first device; 500—second device; 600—memory array; 700—peripheral circuit.

### DETAILED DESCRIPTION

The technical solutions in implementations of the present disclosure will be described clearly and completely below in connection with accompanying drawings of the implementations of the present disclosure. In description of the present disclosure, it is understood that orientation and position relationships indicated by terms “center”, “longitudinal”, “traverse”, “length”, “width”, “thickness”, “upper”, “lower”, “front”, “back”, “left”, “right”, “vertical”, “horizontal”, “top”, “bottom”, “inner”, “outer”, “clockwise” and “counter-clockwise” are those based on the drawings and only for the purpose of facilitating and simplifying the description. There is no indication or implication that the devices or elements as referred to must have any particular orientations and positions, or be constructed or operated in any particular orientations and positions. As a result, they should not be understood as any limitation on the present disclosure. Moreover, the terms “first”, “second” etc. are only used for the purpose of description and should not be understood to indicate or imply relative importance or to designate the number of the referenced technical features implicitly. Therefore, a feature qualified by “first” or “second” may include explicitly or implicitly one or more instances of the feature. In the description of the present disclosure, “a plurality of” means two or more unless otherwise defined explicitly.

It should be understood that terms “first”, “second” etc. may be used to describe various components herein, but are not intended to limit them. Those terms are used to distinguish one component from another. For example, a “first component” may be referred to as a “second component” and likewise a “second component” may be referred to as a “first component” without departing from the scope of the present disclosure.

It should be understood that when a component is described to be “on” or “connected to” another component, it can be directly on or connected to another component or there may be any intervening components. Other terms used to describe relationships between components should be explained likewise.

As used herein, the term “layer” refers to a material portion of a region with a thickness. A layer has a top side and a bottom side, wherein the bottom side is relatively proximate to the substrate and the top side is relatively remote from the substrate. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer may include a plurality of layers. For example, an interconnect layer can include one or more conductor and contact layers (in which contacts and interconnect lines are formed) and one or more dielectric layers.

Herein, cross-sections of a wafer in various directions may be represented in the Cartesian coordinate system (in x, y and z coordinates), where a x-y plane is parallel to the substrate and a z-direction is perpendicular to the substrate.

It is to be noted that the diagrams provided in the implementations of the present disclosure are only used to illustrate the basic conception of the present disclosure schematically, and only drawn in light of related components in the present disclosure, but not according to the numbers, shapes and dimensions of components in practice. In practical implementation, the configurations, numbers and scales of components may be varied, and the layout of the components may be more complicated.

A memory device in the present disclosure may be a wafer or a three-dimensional (3D) memory device, and is also referred as a memory. A 3D memory can be applied to products in the field of communications, consumer electronics, automobiles, aerospace, artificial intelligence or big data and so on. Consumer electronic products include, but not limited to, cellphones, computers, tablets, cameras, intelligent glasses or gaming products.

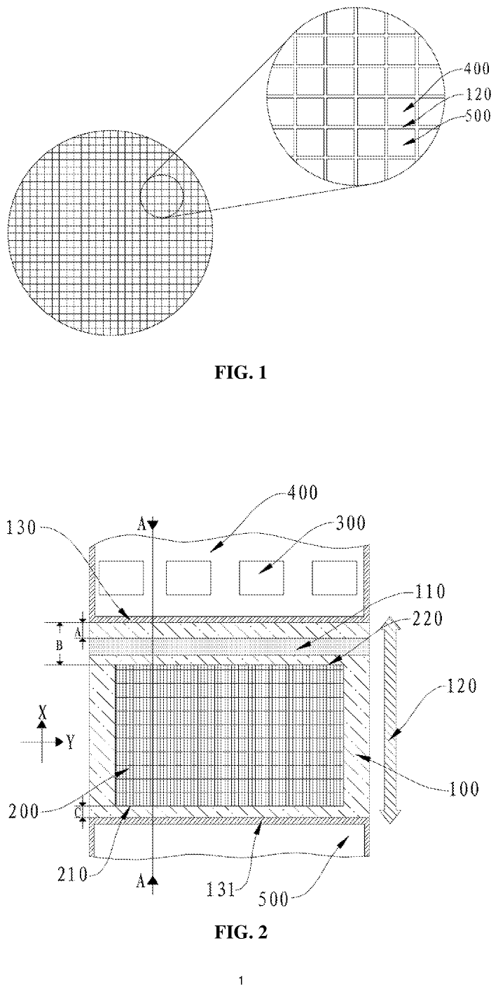

FIG. 1 shows the wafer provided in this application and the partially enlarged structure of the wafer. There are a plurality of intersecting dicing streets 120 on the wafer, which run in different directions and divide the wafer into a plurality of portions. The semiconductor device described in the present disclosure includes a whole wafer or one or more portions thereof as shown in FIG. 1. The wafer in the present disclosure includes a first device 400 and a second device 500, each of which may include one or more portions of the wafer.

The stealth dicing technology in the present disclosure refers to a process, in which a laser is focused inside a wafer to make a crack occur when a certain energy density is reached, resulting in a modified layer. Cleavage will occur in the wafer upwards and downwards in a vertical direction along the modified layer. Then blue tape expansion is performed to complete dicing. The kerf width for dies separated by stealth dicing is nearly zero. Since dicing gaps are narrowed through stealth dicing, stress acting on the dies in dicing is reduced and at the same time the portions separated apart are smoother than those obtained using blade dicing, so that the dicing street can be narrowed and the fracture resistance can be improved for thin dies. An SDBG process is a technology in which the modified layer of the dies will be removed by grinding after stealth dicing of the wafer. Therefore, using an SDBG process, rupture on the front and back surfaces of the dies can be reduced and thin dies of a high strength can be fabricated without processing marks on their side faces. After grinding of the dies, a die attach film (DAF) is used in combination with a die matrix expander (DDS Series) to achieve high-quality separation by expansion in a low-temperature environment. Dicing streets are channels disposed on the wafer to separate the dies. Generally, a plurality of dies are singularized by dicing along the dicing streets. Likewise, in stealth dicing, stealth cleavage lanes are arranged along the dicing streets. In the dicing streets, metal structures are distributed, which are used to imitate connection relationships between internal circuit structures of chips and can be seen as a miniature of the internal circuit structures of the chips. Each tier of circuit structures may need to be a metal structure, which will be connected to an external test equipment to test the functions of the chips after their fabrication and before dicing, ensuring that no damages have been caused to the chips by the fabrication process to satisfy production requirements.

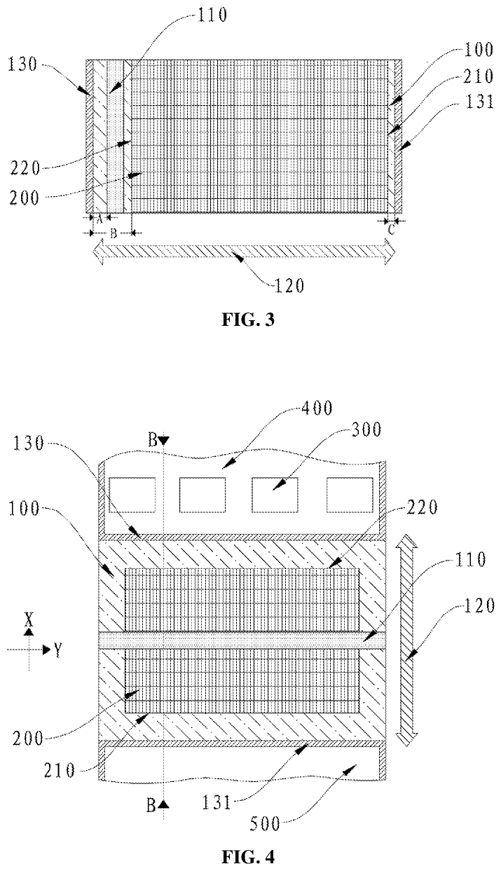

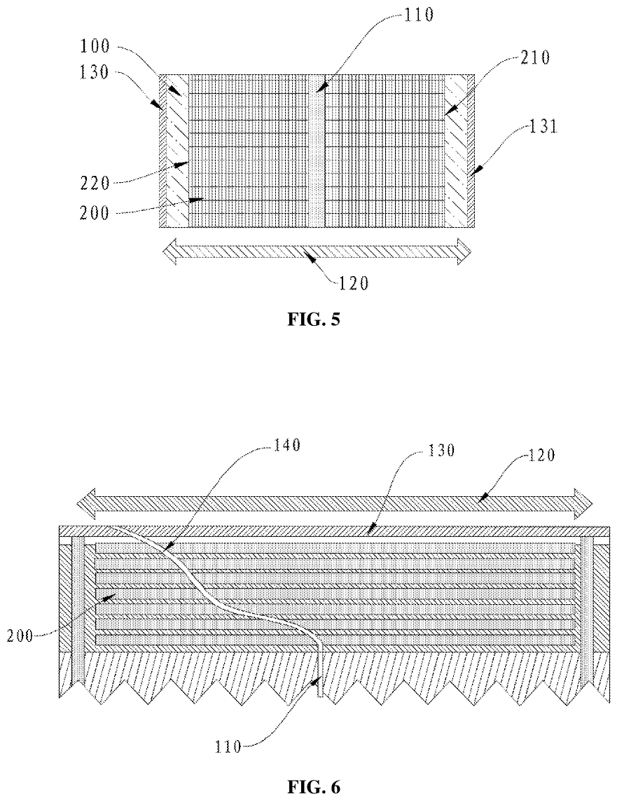

The applicant has noticed that with the development of chip processes, the number of layers of a 3D NAND chip is also increasing and a 3D NAND chip may have hundreds of layers now while it can only have tens of layers originally. The increased number of layers will make processes more complicated, as it has to be ensured that no damage will be caused to the chips by dicing. Stealth dicing is a common safe manner of dicing. As shown in FIGS. 4 and 5, when the number of layers of the chips are small and the stealth cleavage lanes overlap the metal structures, since the metal structures are thin, cracks generated by stealth dicing can penetrate through the metal structures to extend and the metal structures can be separated easily during die separation through expansion. However, when the number of layers of the chips is increased, the thickness of the metal structures is increased correspondingly, and the metal structures may prevent the laser from being focused into the wafer or block the cracks generated by the laser irradiation from extending further downwards, leading to failure of formation of the modified layer or causing non-directional fracture from the cracks in the metal structures as shown in FIG. 6. In the above-described case, the dies are susceptible to fracture during die separation through expansion. Therefore, in order to ensure undamaged dies to be obtained by dicing, the power of the laser for dicing or the number of dicing operations for the dies have to be increased, which dicing process, however, can increase the risk of laser scattering and fracture of the dies correspondingly. To solve the technical problem mentioned above, the following technical solution is proposed by the applicant of the present disclosure to avoid the risks faced by the dies in dicing.

Refer to FIG. 2, which shows a structural diagram of a semiconductor device provided in accordance with an implementation of the present disclosure. The implementation of the present disclosure discloses a semiconductor device including a first device 400 and a dicing street 120 adjoining the first device 400 laterally. In the dicing street 120, a metal structure 200 and a stealth cleavage lane 110 are disposed, wherein the stealth cleavage lane 110 has a first orthogonal projection on the cross-section with the dicing street located therein, the metal structure 200 has a second orthogonal projection on the cross-section with the dicing street located therein, and the first and second orthogonal projections have a space therebetween. It can be understood that the dicing street 120 is the portion used to separate semiconductor devices by dicing and the semiconductor devices may be memory array chips or memories formed by bonding the memory array chips to peripheral circuit chips. In the prior art, a plurality of devices are separated along the dicing street 120 through blade dicing or stealth dicing, and the metal structure 200 disposed in the dicing street 120 is used for test and quality verification of the devices to avoid production of unqualified products. The stealth cleavage lane 110 extends along the dicing street 120 and during stealth dicing a laser is directed on particular positions inside the dicing street 120 to form a corresponding modified layer, which in turn forms the stealth cleavage lane. It is to be noted that the metal structure 200 that originally overlaps the stealth cleavage lane 110 is shifted in position in the present disclosure, so that the stealth cleavage lane 110 does not overlap or intersect the metal structure 200 as seen orthogonally, ensuring that the stealth cleavage lane 110 can avoid the metal structure 200 during stealth dicing for the devices. The cracks generated in stealth dicing can therefore extend in specified directions. After penetrating through the dicing street, the stealth dicing lane 110 forms a plane for stealth cleavage at the splitting position and therefore can be considered as a stealth dicing plane.

With continued reference to FIGS. 1 and 2, in some implementations of the present disclosure, the semiconductor device further includes a second device 500, wherein the first device 400 includes a first sealing ring 130, the second device 500 includes a second sealing ring 131, and the dicing street 120 is located between the first sealing ring 130 and the second sealing ring 131. It can be understood that a semiconductor device includes a plurality of first devices 400 and a plurality of second devices 500 spaced from each other. The first sealing ring 130 and the second sealing ring 131 are both closed annular structures, and both have portions extending in the X direction and portions extending in the Y direction. The channel between adjacent first sealing ring 130 and second sealing ring 131 is the dicing street 120, wherein the dicing street 120 extends in the X direction and/or the Y direction. It is to be noted that the X direction and the Y direction are mutually orthogonal.

With reference to FIGS. 2 and 3, in some implementations of the present disclosure, the metal structure 200 includes a first side edge 220 and a second side edge 210 disposed opposite to each other, wherein the second side edge 210 is closer to the second sealing ring 131 than the first side edge 220 is, the first side edge 220 is closer to the first sealing ring 130 than the second side edge 210 is, and the stealth cleavage lane 110 is disposed between the first side edge 220 and the first sealing ring 130. It can be understood that the metal structure 200 has multiple edges, of which, two ones facing and proximate to the first sealing ring 130 and the second sealing ring 131 respectively are pointed out in the present disclosure. In order to ensure that the stealth cleavage lane 110 has no portion overlapping any portion of the metal structure 200 as seen orthogonally, the first side edge 220 of the metal structure 200 is the one of the side edges that is closest to the first sealing ring 130 and the second side edge 210 is the one of the side edges that is closest to the second sealing ring 131. The metal structure 200 may have various shapes and thus the first side edge 220 and the second side edge 210 may be straight lines, arc lines or zigzag lines. It is to be noted that when the first sealing ring 130 extends in the X direction, the stealth cleavage lane 110 is close to the first sealing ring 130 and extends in the X direction while in the Y direction the stealth cleavage lane 110 is always located between the first sealing ring 130 and the metal structure 200; when the first sealing ring 130 extends in the Y direction, the stealth cleavage lane 110 is close to the first sealing ring 130 and extends in the Y direction while in the X direction the stealth cleavage lane 110 is always located between the first sealing ring 130 and the metal structure 200.

With reference to FIG. 2, in some implementations of the present disclosure, the first device 400 includes pads 300 disposed on the side of the first sealing ring 130 away from the dicing street 120. The pads are interfaces connected between inside of the chip and the package of the chip. The pads include signal input/output, some being interfaces for power and some for ground. The pads connect to logic circuits in the chip internally and to a plurality of pins for the chip externally.

With reference to FIGS. 2 and 3, in some implementations of the present disclosure, the second side edge 210 is spaced from the second sealing ring 131 by at least one unit-length of distance, while the stealth cleavage lane 110 is spaced from the first sealing ring 130 by at least two unit-lengths of distance and the first side edge 220 is spaced from the first sealing ring 130 by at least three unit-lengths of distance. In the present disclosure, one unit-length is 5 μm. It can be understood that the second side edge 210 and the second sealing ring 131 are spaced apart by a distance of at least 5 μm or any other optional value such as 6 μm, 7 μm, 8 μm, 9 μm or 10 μm, while between the first side edge 220 and the first sealing ring 130 a channel needs to be disposed to accommodate the stealth cleavage lane 110, with the channel having a width of at least 15 μm or any other optional value such as 16 μm, 17 μm, 18 μm, 19 μm, 20 μm, 21 μm, 22 μm, 23 μm, 24 μm or 25 μm, and at the same time the stealth cleavage lane 110 and the first sealing ring 130 are spaced apart by a distance of at least 10 μm or any other optional value such as 11 μm, 12 μm, 13 μm, 14 μm, 15 μm, 16 μm, 17 μm or 18 μm. At the same time, in order to prevent the metal structure 200 from being involved in formation of the modified layer during stealth dicing, the stealth cleavage lane 110 and the first side edge 220 are spaced apart by a distance of at least 5 μm.

In some other implementations, the first side edge 220 and the first sealing ring 130 are spaced apart by a first distance B, while the second side edge 210 and the second sealing ring 131 are spaced apart by a second distance C, wherein the first distance B is larger than the second distance C and they satisfy: 1<B/C≤4. It can be understood that the first side edge 220 and the first sealing ring 130 need to have the stealth cleavage lane 110 disposed therebetween while the second side edge 210 and the second sealing ring 131 have a blank space therebetween, so that a greater value should be reserved for the first distance B to facilitate the arrangement of the stealth cleavage lane 110 and subsequent operations of stealth dicing. It can be contemplated that the ratio between the first distance B and the second distance C may also be 1, 1.2, 1.4, 1.5, 1.6, 1.8, 2.0, 2.2, 2.4, 2.5, 2.6, 2.8, 3.0, 3.2, 3.4, 3.5, 3.6, 3.8 or 4.0.

In some other implementations, the stealth cleavage lane 110 and the first sealing ring 130 are spaced apart by a third distance A, wherein the first distance B and the third distance A satisfy: 1<B/A≤3. It can be understood that in order to ensure a certain strength and integrity of the first device 400 after dicing, the stealth cleavage lane 110 and the first device 400 have a safe distance from each other, so that laser scattered will not affect the first device 400 in stealth dicing. It can be contemplated that the ratio between the first distance B and the third distance A may also be 1, 1.2, 1.4, 1.5, 1.6, 1.8, 2.0, 2.2, 2.4, 2.5, 2.6, 2.8, 3.0, 3.2, 3.4, 3.5, 3.6, 3.8 or 4.0.

In some other implementations, the stealth cleavage lane 110 and the first sealing ring 130 are spaced apart by the third distance A. The third distance A has a value in the range of 5≤A≤10 μm, the first distance B has a value in the range of 15≤B≤30 μm, and the second distance C has a value in the range of 5≤B≤15 μm. It can be understood that the stealth cleavage lane 110 and the first sealing ring 130 need to have a safe distance therebetween, which, as the third distance A, may be chosen from a group of values including 5 μm, 6 μm, 7 μm, 8 μm, 9 μm and 10 μm; meanwhile the first side edge 220 of the metal structure 200 and the first sealing ring 130 have an enough dicing distance reserved therebetween, which, as the first distance B, may be chosen from a group of values including 15 μm, 16 μm, 17 μm, 18 μm, 19 μm, 20 μm, 21 μm, 22 μm, 23 μm, 24 μm, 25 μm, 26 μm, 27 μm, 28 μm, 29 μm and 30 μm; and correspondingly the second side edge 210 of the metal structure 200 and the second sealing ring 131 may have a space therebetween with a width, which, as the second distance C, may be chosen from a group of values including 5 μm, 6 μm, 7 μm, 8 μm, 9 μm, 10 μm, 11 μm, 12 μm, 13 μm, 14 μm and 15 μm.

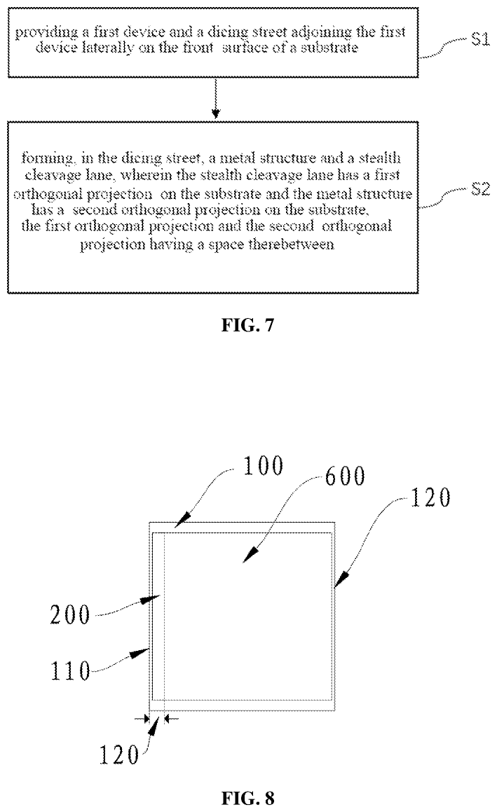

With reference to FIG. 7, some implementations of the present disclosure further provide a fabricating method for a semiconductor device, the method including the following steps.

At step S1, a first device and a dicing street adjoining the first device laterally are provided on the front surface of a substrate 100, which may be a semiconductor substrate 100, for example, silicon (Si), germanium (Ge), SiGe substrate 100, silicon on insulator (SOI), germanium on insulator (GOI) or the like. In other implementations, the semiconductor substrate 100 may be a substrate 100 comprises other element semiconductor or compound semiconductor, and may has a stack structure, e.g., Si/SiGe or the like.

Before formation of the dicing street 120, the first device 400 and the second device 500 are formed on the front surface of the substrate 100. Photoresist is coated on the substrate 100, and photolithography is performed on the photoresist to form circuit patterns, a multi-layered structure is obtained by a deposition process, and channel structures are formed by an etching process and doped with different particles. After rounds of deposition, doping and etching, a plurality of first devices 400 and a plurality of second devices 500 can be obtained. The first sealing ring 130 is formed in the first device 400 and the second sealing ring 131 is formed in the second device 500. The first sealing ring 130 and the second sealing ring 131 are both closed annular structures and both have portions extending in the X direction and portions extending in the Y direction. The dicing street 120 is defined to be the portion between the first sealing ring 130 and the second sealing ring 131. The dicing street 120 separates the first device 400 from the second device 500 along the X direction or the Y direction.

At step S2, in the dicing street 120, the metal structure 200 and the stealth cleavage lane 110 are formed, wherein the stealth dicing lane has a first orthogonal projection on the substrate and the metal structure has a second orthogonal projection on the substrate with the first orthogonal projection and the second orthogonal projection having a space therebetween. It is to be noted firstly that metal structure 200 may be formed in synchronization with the first device 400 and the second device 500, i.e., in the above-mentioned photolithography process the circuit pattern for the metal structure 200 is formed simultaneously and the corresponding metal structure 200 can be obtained through the above-mentioned deposition, doping and etching. It is to be noted that the metal structure 200 includes a first side edge 220 and a second side edge 210 opposite to each other in one direction as well as other side edges having position relationships of no interest in the present disclosure. In the present disclosure, the first side edge 220 of the metal structure 200 is closer to the first sealing ring 130 than the second side edge 210 is, the second side edge 210 is closer to the second sealing ring 131 than the first side edge 220 is, and a first distance B between the first side edge 220 and the first sealing ring 130 is controlled to be larger than a second distance C between the second side edge 210 and the second sealing ring 131 during formation of the metal structure 200.

It can be understood that in stealth dicing a laser needs to be focused inside a wafer to cause cracks in the internal structures of the wafer, so that a modified layer is formed. In stealth dicing for dies, to ensure the laser to be focused properly inside the wafer so as to form directional cracks, the metal structure 200 is offset from the path of laser focusing to prevent the first orthogonal projection of the stealth cleavage lane 110 on the substrate 100 from overlapping the second orthogonal projection of the metal structure 200 on the substrate, i.e., the stealth cleavage lane 110 does not overlap the metal structure 200 as seen orthogonally. As a result, in the stealth dicing of the wafer, the laser is ensured to be focused inside the wafer smoothly and cause corresponding cracks, by which the dies can be separated from each other very well, preventing the dies from being damaged during die separation through expansion.

In some other implementations, the stealth cleavage lane 110 used for stealth laser dicing is formed between the first side edge 220 and the first sealing ring 130, and the substrate 100 is thinned from backside. After internal modification of the substrate 100 by the laser, the substrate 100 is thinned from backside by removing the modified layer through grinding and separation through expansion is performed with a die matrix expander using a DAF in a low-temperature environment to achieve high-quality separation.

In some other implementations, before formation of stealth cleavage lane 110, a protecting layer with marks indicating the extending direction of the stealth cleavage lane 110 is formed at least on the dicing street 120. It can be understood that before formation of stealth cleavage lane 110, a protective layer can be formed on the whole wafer or on the dicing street 120. The protective layer may be an adhesive tape and has marks thereon indicating the extending directions of the stealth cleavage lanes 110. The extending path of the stealth cleavage lane 110 can be identified by dashed lines, dots or arrows to indicate the, so that the positions of points for subsequent stealth dicing operations can be determined accurately to avoid errors in stealth dicing due to mis-position of laser focus. Meanwhile, the protective layer can also adhere the first device 400 to the second device 500 to prevent them from being scattered by an external force and thus to protect them.

In some other implementations, the backside of substrate 100 is covered by a dicing tape, the protecting layer is removed, and die separation through expansion is performed on the first device 400 and the second device 500 using the dicing tape to obtain singularized first device 400 and second device 500. It can be understood that after the substrate 100 is modified and thinned, the first device 400 and the second device 500 need to be separated. First, a dicing tape is adhered to the whole wafer and usually on the backside of the substrate 100. Then the protective layer is removed to avoid die cracking due to its counteraction with the dicing tape and at the same time reduce resistance against separation of the first device 400 and the second device 500. At last singularized first device 400 and second device 500 are obtained through separation.

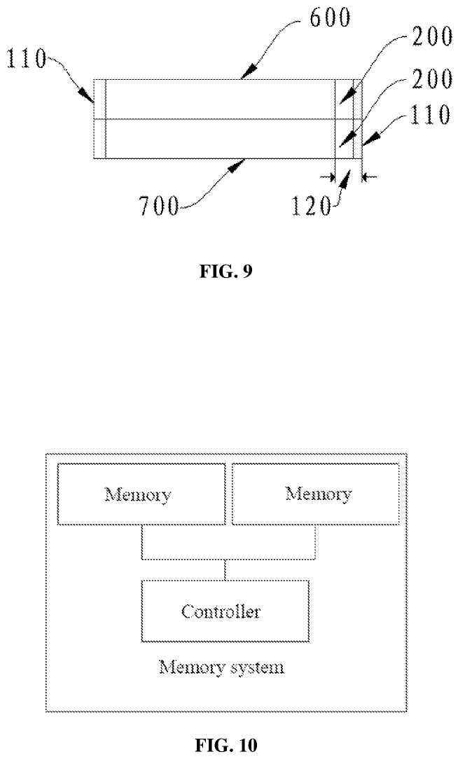

As shown in FIGS. 8 and 9, some implementations of the present disclosure also provide a memory including a memory array 600 and a peripheral circuit 700, wherein the memory array 600 or the peripheral circuit 700 includes a first device 400, a dicing street 120 adjoining the first device 400 laterally and a stealth cleavage lane 110 located in the dicing street 120. The dicing street 120 also has a metal structure 200 located therein. The stealth cleavage lane 110 has a first orthogonal projection on the cross-section of the dicing street 120, the metal structure 200 has a second orthogonal projection on the cross-section of the dicing street 120, and the first and second orthogonal projections have a space therebetween. It is to be noted that the memory array 600 or the peripheral circuit 700 has the stealth cleavage lane 110 before stealth dicing and will have only a dicing plane after stealth dicing. The dicing plane is obtained by dicing through the stealth cleavage lane 110 and can be understood as the stealth cleavage lane 110. Before dicing of the wafer, the semiconductor device may be a single wafer having memory array chips or a single wafer having peripheral circuit chips or may be obtained by bonding a wafer having memory array chips to a wafer having peripheral circuit chips. In some implementations, dicing can be performed after bonding the memory array 600 to the peripheral circuit 700 and the device obtained after dicing can function as a memory.

As shown in FIGS. 8 to 10, some implementations of the present disclosure also provide a memory system including a memory and a controller electrically connected with the memory to control the memory to store data. The memory includes a memory array 600 and a peripheral circuit 700, wherein the memory array 600 or the peripheral circuit 700 includes a first device 400, a dicing street 120 adjoining the first device 400 laterally and a stealth cleavage lane 110 located in the dicing street 120. The dicing street 120 also has a metal structure 200 located therein. The stealth cleavage lane 110 has a first orthogonal projection on the cross-section of the dicing street 120, the metal structure 200 has a second orthogonal projection on the cross-section of the dicing street 120, and the first and second orthogonal projections have a space therebetween. It is to be noted that the memory array 600 or the peripheral circuit 700 has the stealth cleavage lane 110 before stealth dicing and will have only a dicing plane after stealth dicing. The dicing plane is obtained by dicing through the stealth cleavage lane 110 and can be understood as the stealth cleavage lane 110. The memory system may include a plurality of memories, each of the memories being formed by bonding the memory array 600 to the peripheral circuit 700. The memory system is formed after the plurality of memories being connected to a controller 800 to store data.

The semiconductor device, fabricating method, memory and system provided in accordance with implementations of the present disclosure have been introduced above in detail and specific examples are provided to explain the principle and implementations of the present disclosure. Description of the implementations above is only used to facilitate understanding of the technical solutions and the core concept of the present disclosure. It can be understood by those of ordinary skills in the art that the technical solutions described in the foregoing various implementations can be modified or have some technical features therein replaced equivalently without making corresponding technical solutions depart in essence from the scope of the technical solutions in the implementations of the present disclosure.

What is claimed is:

1. A semiconductor device, comprising:
a first device;
a dicing street adjoining the first device laterally;
a metal structure located in the dicing street; and
a stealth cleavage lane extending in the dicing street;
wherein a first orthogonal projection of the stealth cleavage lane on a lateral cross-section of the dicing street is distant from a second orthogonal projection of the metal structure on the lateral cross-section of the dicing street.

2. The semiconductor device of claim 1, further comprising:
a second device,
wherein the first device comprises a first sealing ring, the second device comprises a second sealing ring, and the dicing street is located between the first sealing ring and the second sealing ring.

3. The semiconductor device of claim 2, wherein:
the metal structure comprises a first side edge adjacent to the first sealing ring and a second side edge adjacent to the second sealing ring; and
the stealth cleavage lane is located between the first side edge and the first sealing ring.

4. The semiconductor device of claim 2, wherein the first device comprises at least one pad disposed on a side of the first sealing ring away from the dicing street.

5. The semiconductor device of claim 3, wherein:
the second side edge is distant from the second sealing ring by at least one unit-length of distance;
the stealth cleavage lane is distant from the first sealing ring by at least two unit-lengths of distance; and
the first side edge is distant from the first sealing ring by at least three unit-lengths of distance.

6. The semiconductor device of claim 5, wherein each unit-length is about 5 μm.

7. The semiconductor device of claim 3, wherein:
a first distance between the first side edge and the first sealing ring is greater than a second distance between the second side edge and the second sealing ring.

8. The semiconductor device of claim 7, wherein:
a ratio between the first distance and the second distance is greater than 1 and less than or equal to 4.

9. The semiconductor device of claim 7, wherein a ratio between the first distance and a third distance between the stealth cleavage lane and the first sealing ring is greater than 1 and less than or equal to 3.

10. The semiconductor device of claim 9, wherein the third distance is between a range from about 5 μm to about 10 μm.

11. The semiconductor device of claim 7, wherein the first distance is between a range from about 15 μm to about 30 μm.

12. The semiconductor device of claim 7, wherein the second distance is between a range from about 5 μm to about 15 μm.

13. The semiconductor device of claim 1, wherein the first device comprises one of a memory array and a peripheral circuit.

14. A method for fabricating a semiconductor device, comprising:
forming a first device and a dicing street adjoining the first device laterally on a front surface of a substrate;
forming a metal structure and a stealth cleavage lane in the dicing street,
wherein a first orthogonal projection of the stealth cleavage lane on a lateral cross-section of the dicing street is distant from a second orthogonal projection of the metal structure on the lateral cross-section of the dicing street.

15. The method of claim 14, further comprising:
forming a second device including a second sealing ring on the substrate;
wherein forming the first device including forming a first sealing ring, and the dicing street is formed between the first sealing ring and the second sealing ring.

16. The method claim 15, wherein:
a first distance between a first side edge and the first sealing ring is formed greater than a second distance between a second side edge and the second sealing ring.

17. The method of claim 16, wherein forming the stealth cleavage lane comprises:
forming the stealth cleavage lane between the first side edge and the first sealing ring by stealth laser dicing; and
the method further comprises thinning the substrate from a backside to form a thinned surface.

18. The method of claim 17, further comprising:
before forming the stealth cleavage lane, forming a protective layer at least on the dicing street, wherein the protective layer has a mark indicating an extending direction of the stealth cleavage lane.

19. The method of claim 18, further comprising:
disposing dicing tape covering the thinned surface of the substrate;
removing the protective layer; and
separating the first device and the second device by using the dicing tape.

20. A memory device, comprising:
a memory array; and
a peripheral circuit coupled with the memory array,
wherein the memory array or the peripheral circuit comprising:
a first device,
a dicing street adjoining the first device laterally,
a metal structure located in the dicing street, and
a stealth cleavage lane extending in the dicing street,
wherein a first orthogonal projection of the stealth cleavage lane on a lateral cross-section of the dicing street is distant from a second orthogonal projection of the metal structure on the lateral cross-section of the dicing street.
